(19) United States
(12) Patent Application Publication
(10) Pub. No.: US 2015/0333228 A1
(43) Pub. Date: Nov. 19, 2015

(54) HIGH-BRIGHTNESS SEMICONDUCTOR LIGHT-EMITTING DEVICE HAVING EXCELLENT CURRENT DISPERSION EFFECT BY INCLUDING SEPARATION REGION

(71) Applicant: ILJIN LED CO., LTD., Ansan-si Gyeonggi-do (KR)

(72) Inventors: Jung-Sub SONG, Daejeon (KR); Dong-Woo KIM, Seoul (KR); Seung-Joo HWANG, Suncheon-si, Jeollanam-do (KR); Keuk KIM, Seongnam-si, Gyeonggi-do (KR); Won-Jin CHOI, Seongnam-si, Gyeonggi-do (KR)

(21) Appl. No.: 14/648,848

(22) PCT Filed: Nov. 27, 2013
(86) PCT No.: PCT/KR2013/010869

§ 371 Date: Jun. 1, 2015

(30) Foreign Application Priority Data
Dec. 3, 2012 (KR) 10-2012-0138806

(51) Int. Cl. H01L 33/38; H01L 33/00; H01L 33/40; H01L 33/14; H01L 33/42

(52) U.S. Cl. CPC H01L 33/387; H01L 33/14; H01L 33/42; H01L 33/40; H01L 33/0075; H01L 2933/0016

(57) ABSTRACT

The present invention relates to a semiconductor light-emitting device including a separation region for separating a light-emitting surface, so as to exhibit an excellent current dispersion effect and improve brightness characteristics. The semiconductor light-emitting device of the present invention can obtain the effect for improving uniformity of effective current density by including the separation region for separating the light-emitting region, and can expect an improvement in optical efficiency through the excellent current dispersion effect.

### TECHNICAL FIELD

The present invention relates to a semiconductor light-emitting device including a separation region for separating a light-emitting region and having an excellent current spreading effect and an improved brightness characteristic.

### BACKGROUND ART

FIG. 1 is a cross-sectional view illustrating a cross section of a conventional semiconductor light-emitting device.

Referring to FIG. 1, a nitride-based light-emitting device is grown from a growth substrate 11, and includes an n type nitride semiconductor layer 12, an active layer 13, and a p type nitride semiconductor layer 14.

Furthermore, in order to inject electrons into the n type nitride semiconductor layer 12, an n-side electrode pad 16 electrically connected to the n type nitride semiconductor layer 12 is formed. Furthermore, in order to inject holes into the p type nitride semiconductor layer 14, a p-side electrode pad 15 electrically connected to the p type nitride semiconductor layer 14 is formed.

However, an electric current is not uniformly spread within the p type nitride semiconductor layer and an electric current is concentrated on a portion where the p-side electrode pad has been formed because the p type nitride semiconductor layer has high resistivity. Furthermore, the electric current exits to the n-side electrode pad through the semiconductor layers. Accordingly, there is a problem in that an electric current intensively flows through the corner of a light-emitting diode because an electric current is concentrated on a portion that belongs to the n type nitride semiconductor layer and where the n-side electrode pad has been formed. Such a concentration of the electric current leads to a reduction of a light-emitting region, thereby deteriorating light-emitting efficiency.

In particular, a planar type light-emitting device in which two electrodes are arranged on top of a light-emitting structure almost horizontally is problematic in that a valid area participating in light emission is not wide because a current flow is not uniformly distributed over the entire light-emitting region compared to a vertical type light-emitting device.

For a high output, the area of a light-emitting device, such as a light-emitting device for a light, is gradually increasing 1 mm² or more. However, as the area of the light-emitting device increases, it is more difficult to realize a uniform current distribution. Such current distribution efficiency problem according to a larger size has been recognized as an important technical problem in semiconductor light-emitting devices.

In a prior art, in order to improve current density and area efficiency, research has been chiefly carried out on improving a variety of types and arrangements of a p-side electrode and an n-side electrode. For example, U.S. Pat. No. 6,486,499 discloses that the n-side electrode and the p-side electrode include a plurality of fingers that are spaced apart from each other at a specific interval, extended, and engaged with each other in order to provide an additional current path, secure a wide valid light-emitting area, and form a uniform current flow through such an electrode structure.

Even in such an electrode structure, output efficiency is deteriorated and there is a limit to current spreading efficiency because current density increases in the p type semiconductor layer near the p-side electrode.

Accordingly, there is a need to continue to develop a semiconductor light-emitting device capable of uniformly spreading an electric current flowing through semiconductor layers.

### DISCLOSURE

### Technical Problem

As the results of research and efforts to develop a semiconductor light-emitting device capable of improving a light-emitting output, embodiments of the present invention capable of improving brightness by maximizing a current spreading effect have been completed by configuring a semiconductor light-emitting device in such a manner that a first extension electrode configured to electrically connect a first semiconductor layer, a second electrode contact layer electrically connected to a second semiconductor layer, and a second extension electrode are formed and a separation region configured to separate the second electrode contact layer into a plurality of regions is formed so that the second electrode contact layers are spaced apart from each other.

An object of the present invention is to provide a semiconductor light-emitting device including a separation region for separating a light-emitting region in order to achieve an excellent current spreading effect.

### Technical Solution

In accordance with an aspect of the present invention, there is provided a semiconductor light-emitting device, including a first extension electrode electrically connected to the first semiconductor layer, a plurality of second electrode contact layers electrically connected to the second semiconductor layer and spaced apart from each other, and a second extension electrode electrically connected to the plurality of second electrode contact layers. The second electrode contact layer is separated into a plurality of second electrode contact layers by a separation region.

Furthermore, in the semiconductor light-emitting device in accordance with an embodiment of the present invention, the second extension electrode is formed to traverse part of the separation region.

Furthermore, in the semiconductor light-emitting device in accordance with an embodiment of the present invention, the plurality of second electrode contact layers separated by the separation region has uniform horizontal areas.

Furthermore, in the semiconductor light-emitting device in accordance with an embodiment of the present invention, the second electrode contact layer is made of a material including one type or two types or more selected from ITO, CIO, ZnO, NiO, In₂O₃, and IZO.

Furthermore, in the semiconductor light-emitting device in accordance with an embodiment of the present invention, the width of the separation region is in a range of 0.5˜20 μm.

Furthermore, the semiconductor light-emitting device in accordance with an embodiment of the present invention includes a contact hole for current spreading configured to expose the first semiconductor layer. The first extension electrode is electrically connected to the first semiconductor layer exposed by the contact hole for current spreading.

Furthermore, the semiconductor light-emitting device in accordance with an embodiment of the present invention further includes a first electrode pad electrically connected to the first extension electrode and a second electrode pad electrically connected to the second extension electrode.

In accordance with another aspect of the present invention, there is provided a method of manufacturing a semiconductor light-emitting device, including forming a first semiconductor layer, an active layer, and a second semiconductor layer, forming a second electrode contact layer over the second semiconductor layer, forming a separation region by etching some region of the second electrode contact layer so that the second electrode contact layer is separated into a plurality of regions, forming a second extension electrode over the second electrode contact layer separated into the plurality of regions and the second semiconductor layer exposed to the separation region, etching the active layer and the second semiconductor layer so that some region of the first semiconductor layer is externally exposed, and forming a first extension electrode over the exposed first semiconductor layer.

### Advantageous Effects

The semiconductor light-emitting device in accordance with an embodiment of the present invention is advantageous in that it can improve the uniformity of a valid current density and can improve light efficiency due to an excellent current spreading effect because it includes the separation region for separating the light-emitting region.

### DESCRIPTION OF DRAWINGS

FIG. 1 is a cross-sectional view illustrating a cross section of a conventional semiconductor light-emitting device.

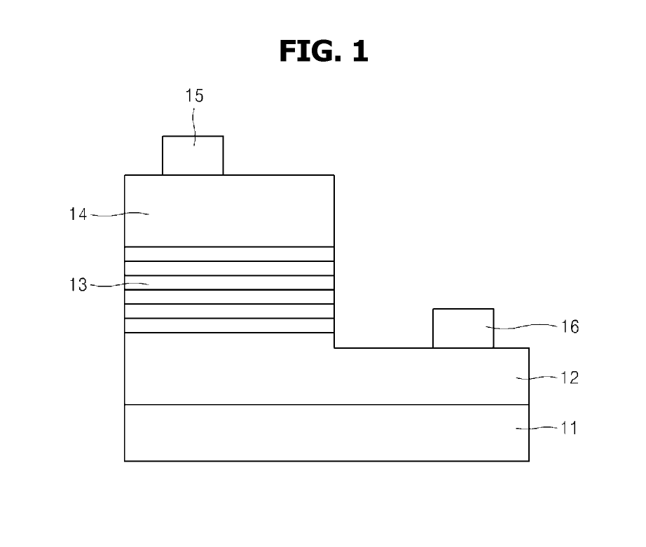

FIG. 2 is a plan view illustrating a semiconductor light-emitting device in accordance with an embodiment of the present invention.

FIG. 3 is a cross-sectional view of the semiconductor light-emitting device taken along line A-A of FIG. 2.

FIG. 4 is a cross-sectional view of the semiconductor light-emitting device taken along line B-B of FIG. 2.

FIG. 5 illustrates an example of an n-side extension electrode formed using a contact hole for current spreading.

FIG. 6 illustrates another example of an n-side extension electrode formed using a contact hole for current spreading.

FIG. 7 is a plan view illustrating a semiconductor light-emitting device in accordance with another embodiment of the present invention.

### BEST MODE

Hereinafter, semiconductor light-emitting devices according to embodiments of the present invention are described in detail with reference to the accompanying drawings.

In the following embodiments, a first semiconductor layer is represented as an n type nitride layer, a second semiconductor layer is represented as a p type nitride layer, a second electrode contact layer is represented as a p-contact layer, a first extension electrode is represented as an n-side extension electrode, a second extension electrode is represented as a p-side extension electrode, a first electrode pad is represented as an n-side electrode pad, and a second electrode pad is represented as a p-side electrode pad.

Furthermore, in this specification, when it is described that one part, such as a layer, film, region, or plate, is “on” or “over” or “below” or “under” the other part, it means not only that one part is placed “right on” or right “below” the other part, but also that a third part may be placed between one part and the other part. Furthermore, in the drawings, the thicknesses of some layers or regions have been enlarged in order to clearly represent several layers and regions or for convenience of description.

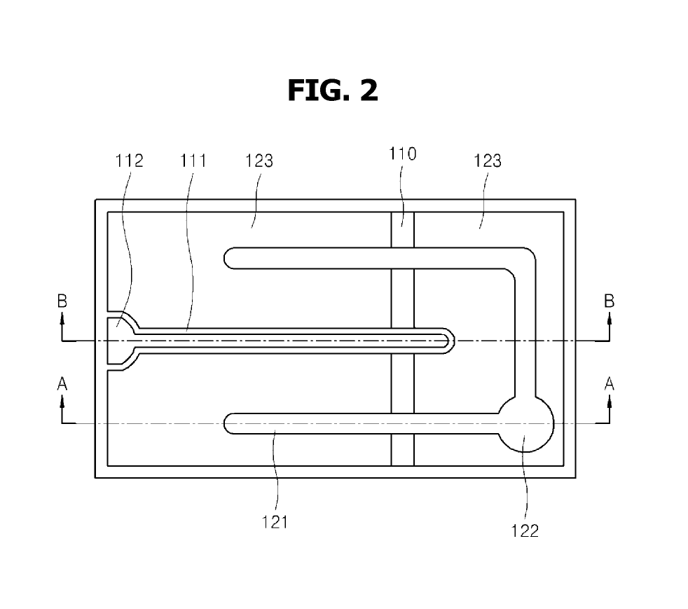

FIG. 2 is a plan view illustrating a semiconductor light-emitting device in accordance with an embodiment of the present invention.

As illustrated in FIG. 2, the light-emitting device in accordance with an embodiment of the present invention includes a separation region 110 configured to separate a light-emitting region. The light-emitting device further includes an n-side extension electrode 111 configured to electrically connect an n type nitride layer exposed by mesa etching and a p-side extension electrode 121. The -side extension electrode 121 is electrically connected to a p-side electrode pad 122 placed on some of a top surface of a p type nitride layer, thus forming a p-side electrode unit. The n-side extension electrode 111 is electrically insulated from the p-side extension electrode 121.

The p-side extension electrode 121 is formed to traverse part of the separation region 110. The separation region 110 is configured in such a way as to traverse part of the p-side extension electrode 121. Furthermore, both the n-side extension electrode 111 and the p-side extension electrode 121 may be formed in such a way as to traverse part of the separation region 110.

As illustrated in FIG. 2, the region of a p-contact layer 123 formed over the p type nitride layer may be separated into three regions by the separation region 110. The number of p-contact layer regions separated by the separation region may be different depending on the shape of the separation region.

In this case, the separation region 110 may be formed so that the regions of the p-contact layer separated by the separation region 110 have uniform horizontal areas. The horizontal areas of the separated regions of the p-contact layer may have a difference of 10% or less by taking into consideration an error in the manufacture process. That is, the horizontal area of the p-contact layer 123 means a light-emitting region other than a non-light-emitting region including the n-side extension electrode. The horizontal areas of the p-contact layer 123 may be uniformly separated on the basis of the area other than the region in which the p-side extension electrode 121 and the p-side electrode pad 122 are formed.

Each of the n-side extension electrode 111 and the p-side extension electrode 121 may be 1˜100 μm and may be controlled in a range of 5˜50 μm, but is not limited thereto.

A single n-side extension electrode 111 or two or more n-side extension electrodes 111 may be electrically connected to an n-side electrode pad 112. The n-side extension electrode 111 may be formed in a straight line shape not having a curved point or may be formed to have one or more curved points.

Furthermore, a single-side extension electrode 121 or one or more p-side extension electrodes 121 may be electrically connected to the p-side electrode pad 122. If the two or more p-side extension electrodes 121 are formed, the ends of the two or more p-side extension electrodes 121 that are not connected to the p-side electrode pad 122 and that are placed on the opposite side may be spaced apart from each other or may be formed in a closed shape on the basis of the p-side electrode pad 122.

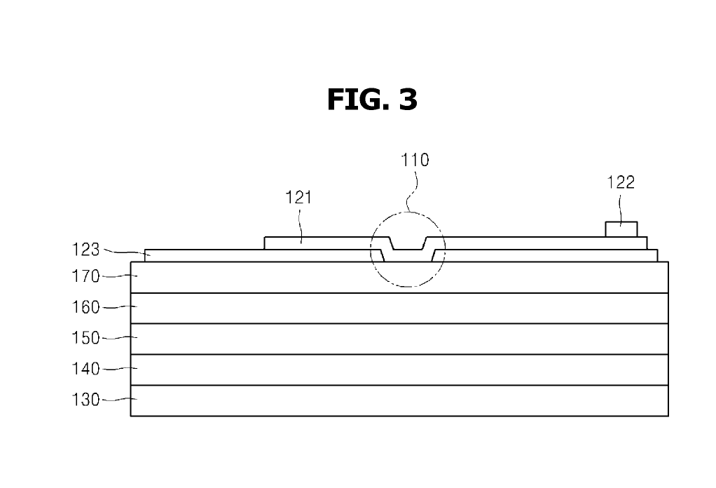

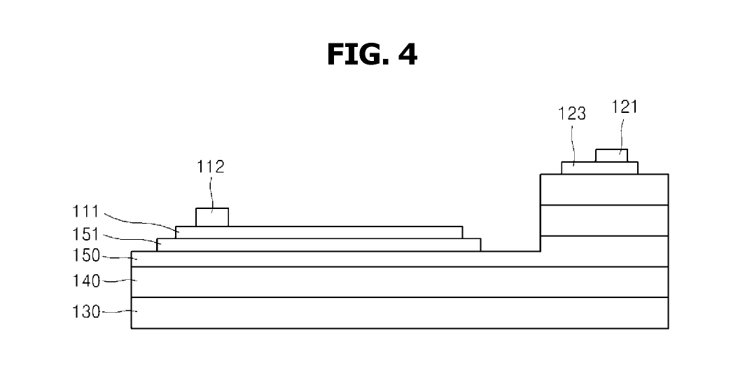

In order to describe a more detailed configuration, FIGS. 3 and 4 illustrate cross sections of the semiconductor light-emitting device taken along lines A-A and B-B of FIG. 2.

As illustrated in FIG. 3, in the semiconductor light-emitting device in accordance with an embodiment of the present invention, a buffer layer 140, an n type nitride layer 150, an active layer 160, and a p type nitride layer 170 are stacked over a substrate 130.

The substrate 130 may be made of a compound, such as SiC, Si, GaN, ZnO, GaAs, GaP, LiAl₂O₃, BN, or AlN, in addition to sapphire. Furthermore, the buffer layer 140 may be selectively formed in order to solve lattice mismatching between the substrate 130 and the n type nitride layer 150 and may be made of AlN or GaN, for example.

The n type nitride layer 150 is formed on the substrate 130 or the buffer layer 140 and may be made of nitride doped with an n type dopant. Silicon (Si), germanium (Ge), or in (Sn) may be used as the n type dopant. In this case, the n type nitride layer 150 may have a stack structure in which a first layer made of n type AlGaN doped with Si or undoped AlGaN and a second layer made of undoped GaN or n type GaN doped with Si are alternately formed. The n type nitride layer 150 may be grown into a single n type nitride layer, but may have the stack structure of the first layer and the second layer so that it functions as a carrier restriction layer not having a crack and having excellent crystallinity.

The active layer 160 may have a single quantum well structure or multi-quantum well structure between the n type nitride layer 150 and the p type nitride layer 170. Electrons flowing through the n type nitride layer 150 and holes flowing through the p type nitride layer 170 are recombined in the active layer 160, thereby generating light. In the present embodiment, the active layer 160 has been illustrated as having a multi-quantum well structure. In this case, each of a quantum barrier layer and a quantum well layer may be made of AlₓGa_{y}In_{z}N (wherein x+y+z=1, 0≦x≦1, 0≦y≦1, and 0≦z≦1). The active layer 160 configured to have the quantum barrier layer and the quantum well layer repeatedly formed therein can suppress spontaneous polarization attributable to generated stress and deformation.

The p type nitride layer 170 is made of nitride doped with a p type dopant. Magnesium (Mg), zinc (Zn), or cadmium (Cd) may be used as the p type dopant. In this case, the p type nitride layer may have a structure in which a first layer made of p type AlGaN doped with Mg or undoped AlGaN and a second layer made of undoped GaN or p type GaN doped with Mg are alternately stacked. Furthermore, like the n type nitride layer 150, the p type nitride layer 170 may be grown into a single p type nitride layer, but may have the stack structure so that it functions as a carrier restriction layer not having a crack and having excellent crystallinity.

A p-side extension electrode 121 and a p-side electrode pad 122 electrically connected to the p-side extension electrode are formed over the p type nitride layer 170. Furthermore, a p-contact layer 123 is formed under the p-side extension electrode 121. The p-contact layer 123 is subject to an ohmic contact with the p type nitride layer 170, and thus functions to reduce contact resistance. The p-contact layer 123 may be made of transparent conductive oxide and may be made of one type or two or more types selected from ITO, CIO, ZnO, NiO, In₂O₃, and IZO.

In particular, the p-contact layer 123 is separated into a plurality of layers by the separation region 110, and the plurality of separated p-contact layers 123 is spaced apart from each other. Accordingly, the separation region 110 means the space where the plurality of p-contact layers 123 are spaced apart from each other. In this case, the plurality of p-contact layers 123 may be electrically connected by the p-side extension electrode 121.

The separation region 110 may be formed by a process of etching part of the p-contact layer 123. If photoresist is used as a mask, the separation region 110 may be formed using a method, such as photolithography, electron beam (e-beam) lithography, ion beam lithography, extreme ultraviolet lithography, proximity X-ray lithography, or nano imprint lithography. Furthermore, such a method may include dry or we etching.

The width of the separation region 110, that is, the distance between the p-contact layers 123 spaced apart from each other, may be in a range of 0.5˜20 μm and may be suitably in a range of 3˜10 μm.

As illustrated in FIG. 4, an n-side extension electrode 111 and an n-side electrode pad 112 electrically connected to the n-side extension electrode are formed on an exposed top surface of the n type nitride layer 150. The n-side extension electrode 111 is formed up to the p type nitride layer 170, the p-contact layer 123, and the p-side extension electrode 121. Next, some region of the n-side extension electrode 111 is subject to lithography etching, and thus the n-side extension electrode 111 is formed over the n type nitride layer 150 that has been externally exposed.

Furthermore, an n-contact layer 151 may be further formed under the n-side extension electrode 111. The n-contact layer 151 is subject to ohmic contact with the n type nitride 150, thus functioning to reduce contact resistance. The n-contact layer 151 may be made of transparent conductive oxide, and the material of the n-contact layer 151 may include elements, such as In, Sn, Al, Zn, or Ga.

Furthermore, the n-side extension electrode 111 and the n-side electrode pad 112 may be formed in an exposed region of the n type nitride layer 150 that has been formed from the p-contact layer 123 to part of the n type nitride layer 150 through lithography etching.

The light-emitting device in accordance with an embodiment of the present invention may include a contact hole for current spreading formed to expose the n type nitride layer 150 through the p type nitride layer 170 and the active layer 160.

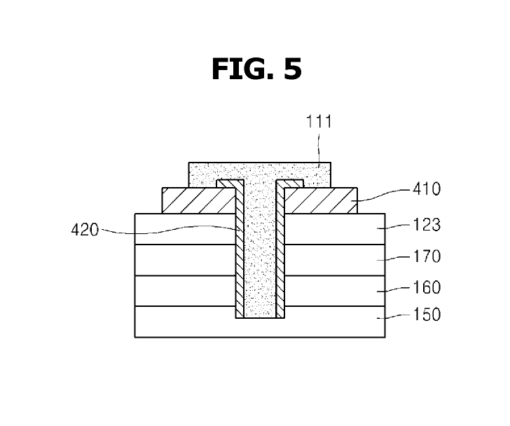

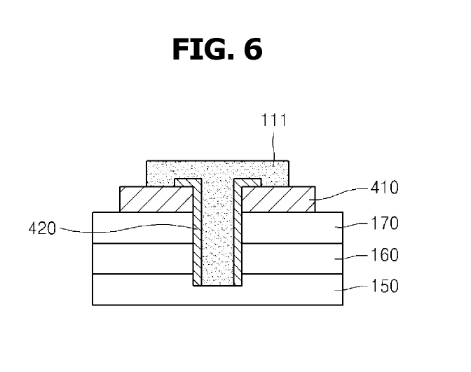

FIG. 5 illustrates an example of an n-side extension electrode formed using a contact hole for current spreading, and FIG. 6 illustrates another example of an n-side extension electrode formed using a contact hole for current spreading. In FIGS. 5 and 6, only one contact hole for current spreading has been illustrated as being formed, but a plurality of the contact holes for current spreading may be formed.

If the p-contact layer 123 is formed on the entire surface, as in the example of FIG. 5, the contact hole for current spreading may be formed using a method of forming an upper insulating layer 410 on some region of the p-contact layer 123, forming a hole that penetrates the upper insulating layer 410, the p-contact layer 123, the p type nitride layer 170, and the active layer 160, and forming a side insulating layer 420 on the inner wall of the hole.

In contrast, if the p-contact layer 123 is formed in some region only, as in the example of FIG. 6, the contact hole for current spreading may be formed using a method of forming the upper insulating layer 410 on some region that belongs to the p type nitride layer 170 and in which the p-contact layer 123 has not been formed, forming a hole that penetrates the upper insulating layer 410, the p type nitride layer 170, and the active layer 160, and forming the side insulating layer 420 on the inner wall of the hole.

After the contact hole for current spreading is formed, the n-side extension electrode 111 may be formed within the contact hole for current spreading and on the upper insulating layer 410, and the n type nitride layer 150 and the n-side extension electrode 111 may be electrically connected by the contact hole for current spreading.

The n-side extension electrode 111 is electrically connected to the n type nitride layer 150 exposed by the contact hole for current spreading. Accordingly, a light-emitting region can be increased, and current spreading can be promoted. In this case, there is a need for the side insulating layer 420 for isolating the sidewall of the contact hole from the n-side extension electrode 111. The side insulating layer 420 may be made of silicon oxide or silicon nitride and may be formed using a plasma enhanced chemical vapor deposition (PECVD) method, a sputtering method, an MOCVD method, or an E-beam evaporation method.

An effect in which the uniformity of a valid current density is improved can be expected, current density can be improved, and brightness can be increased because the second electrode contact layer corresponding to a light-emitting surface is separated and formed by the separation region as described above.

Semiconductor light-emitting devices in accordance with embodiments of the present invention are described in more detail below.

### Embodiment 1

In order to configure a semiconductor light-emitting device, such as that of FIGS. 2 to 4, GaN was applied to a sapphire substrate as the nitride layer of a nitride light-emitting device. A common Au-based electrode was applied as an extension electrode. A separation region was formed as illustrated in FIG. 2, thereby fabricating the nitride light-emitting device.

### Embodiment 2

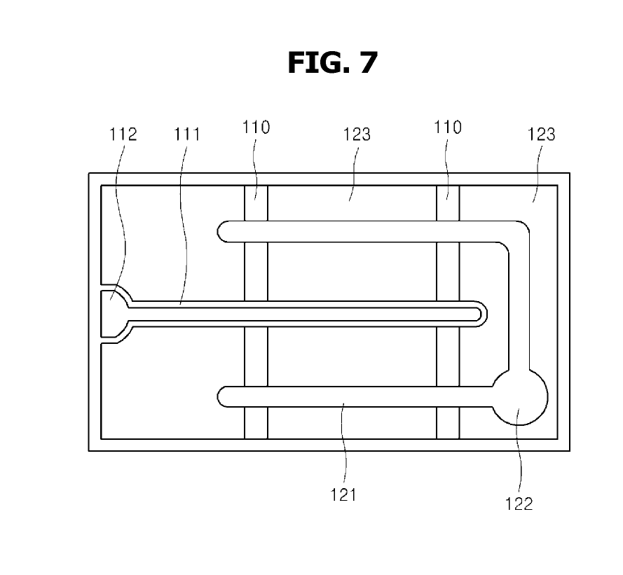

A nitride light-emitting device was fabricated using the same method as that of Embodiment 1 except that the separation region was additionally formed as illustrated in FIG. 7.

### Comparison Example

A nitride light-emitting device was fabricated using the same method as that of Embodiment 1 except that a separate separation region was not formed.

Light-emitting outputs in the light-emitting devices of Embodiments 1 and 2 and Comparison example were measured by applying the same current of 120 mA in the package state. The results of the measurement are illustrated in Table 1.

TABLE 1

| | EMBODIMENT | EMBODIMENT | COMPARISON |
|---|---|---|---|
| | 1 | 2 | EXAMPLE |
| Optical power | 201 | 203 | 198 |
| (mW) | | | |

From Table 1, it may be seen that the light-emitting device of Embodiment 1 or 2 has a better light output characteristic of about 3% or more than Comparison example and the light-emitting device of Embodiment 1 or 2 can have an excellent light output characteristic.

Although the present invention has been described in connection with the embodiments illustrated in the drawings, the embodiments are only illustrative. Those skilled in the art to which the present invention pertains may understand that various other modifications and equivalent embodiments are possible. Accordingly, the true technical scope of the present invention should be determined by the technical spirit of the following claims.

1. A semiconductor light-emitting device comprising a first semiconductor layer, an active layer, and a second semiconductor layer, comprising:
a first extension electrode electrically connected to the first semiconductor layer;
a plurality of second electrode contact layers electrically connected to the second semiconductor layer and spaced apart from each other; and
a second extension electrode electrically connected to the plurality of second electrode contact layers,
wherein the second electrode contact layer is separated into a plurality of second electrode contact layers by a separation region.

2. The semiconductor light-emitting device according to claim 1, wherein the second extension electrode is formed to traverse part of the separation region.

3. The semiconductor light-emitting device according to claim 1, wherein the first extension electrode and the second extension electrode are formed to traverse part of the separation region.

4. The semiconductor light-emitting device according to claim 1, wherein the plurality of second electrode contact layers separated by the separation region has uniform horizontal areas.

5. The semiconductor light-emitting device according to claim 1, wherein the second electrode contact layer is made of a material comprising one type or two types or more selected from ITO, CIO, ZnO, NiO, In₂O₃, and IZO.

6. The semiconductor light-emitting device according to claim 1, wherein a width of the separation region is in a range of 0.5˜20 μm.

7. The semiconductor light-emitting device according to claim 1, wherein:
the first semiconductor layer is exposed, and
the first extension electrode is formed over the first semiconductor layer.

8. The semiconductor light-emitting device according to claim 1, further comprising:
an upper insulating layer formed in some region of the second electrode contact layer; and
a contact hole for current spreading configured to penetrate the upper insulating layer, the second electrode contact layer, the second semiconductor layer, and the active layer,
wherein the first semiconductor layer and the first extension electrode are electrically connected by the contact hole for current spreading.

9. The semiconductor light-emitting device according to claim 1, further comprising:
an upper insulating layer formed in some region of the second semiconductor layer; and
a contact hole for current spreading configured to penetrate the upper insulating layer, the second semiconductor layer, and the active layer, and
wherein the first semiconductor layer and the first extension electrode are electrically connected by the contact hole for current spreading.

10. The semiconductor light-emitting device according to claim 1, further comprising:
a first electrode pad electrically connected to the first extension electrode, and
a second electrode pad electrically connected to the second extension electrode.

11. A method of manufacturing a semiconductor light-emitting device, comprising steps of:
forming a first semiconductor layer, an active layer, and a second semiconductor layer;
forming a second electrode contact layer over the second semiconductor layer;
forming a separation region by etching some region of the second electrode contact layer so that the second electrode contact layer is separated into a plurality of regions;
forming a second extension electrode over the second electrode contact layer separated into the plurality of regions and the second semiconductor layer exposed to the separation region;
etching the active layer and the second semiconductor layer so that some region of the first semiconductor layer is externally exposed; and
forming a first extension electrode over the exposed first semiconductor layer.

12. The method according to claim 11, wherein the step of etching the active layer and the second semiconductor layer comprises steps of:
forming the upper insulating layer in some region of the second electrode contact layer,
forming a contact hole for current spreading configured to have the first semiconductor layer exposed through the upper insulating layer, the second electrode contact layer, the second semiconductor layer, and the active layer by etching, and
forming a side insulating layer on an inner wall of the contact hole for current spreading.

13. The method according to claim 12, wherein the step of forming the first extension electrode over the exposed first semiconductor layer comprises forming a first extension electrode within the contact hole for current spreading and over the upper insulator.

14. The method according to claim 11, wherein:
the step of forming the second electrode contact layer over the second semiconductor layer comprises forming the second electrode contact layer in regions other than some region of the second semiconductor layer, and
the step of etching the active layer and the second semiconductor layer comprises steps of:
forming an upper insulating layer over part of the second semiconductor layer in which the second electrode contact layer has not been formed,
forming a contact hole for current spreading configured to have the first semiconductor layer exposed through the upper insulating layer, the second semiconductor layer, and the active layer by etching, and
forming a side insulating layer on a sidewall of the contact hole for current spreading.

15. The method according to claim 14, wherein the step of forming the first extension electrode over the exposed first semiconductor layer comprises forming the first extension electrode within the contact hole for current spreading and over the upper insulating layer.

16. The method according to claim 11, further comprising steps of:
forming a first electrode pad electrically connected to the first extension electrode; and
forming a second electrode pad electrically connected to the second extension electrode.
